(19) United States
(12) Patent Application Publication
(10) Pub. No.: US 2026/0075747 A1
(43) Pub. Date: Mar. 12, 2026

(54) STEP-SHAPED COVER FOR AIR MOVER

(71) Applicant: Dell Products L.P., Round Rock, TX (US)

(72) Inventor: Qinghong HE, Austin, TX (US)

(73) Assignee: Dell Products L.P., Round Rock, TX (US)

(21) Appl. No.: 18/828,413

(22) Filed: Sep. 9, 2024

(51) Int. Cl. H05K 7/20; G06F 1/20

(52) U.S. Cl. CPC H05K 7/20172; G06F 1/203

(57) ABSTRACT

An information handling system may include a housing, an information handling resource housed within the housing, a first air intake vent formed in the housing, a second air intake vent formed in the housing, a first air mover located proximate to the first air intake vent and configured to draw air into the housing via the first air intake vent, and a second air mover located substantially further away from the first air intake vent than the first air mover, located substantially further away from the second air intake vent than the first air mover is located from the first air intake vent, and configured to draw air into the housing via the second air intake vent.

### TECHNICAL FIELD

The present disclosure relates in general to information handling systems, and more particularly to cooling of information handling system components using one or more air movers, including an air mover shaped to account for lack of air vents proximate to the air mover.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

In conventional notebook computers (e.g., laptops), an air mover may draw air into an information handling system through intake vents formed in a housing of the information handling system and located under the air mover (e.g., on the “D-cover” of the notebook computer opposite a keyboard of the notebook computer). Such air flow path may have a low intake airflow impedance, resulting in a high operating airflow and low thermal module temperature. While the thermal module temperature directly affects a central processing unit (CPU) or graphics processing unit (GPU) temperature, its influence on the skin temperature of the housing of the information handling system is indirect. In many cases, a CPU and/or GPU must be overcooled to maintain a suitable skin temperature.

### SUMMARY

In accordance with the teachings of the present disclosure, the disadvantages and problems associated with traditional approaches to cooling information handling system components may be substantially reduced or eliminated.

In accordance with embodiments of the present disclosure, an information handling system may include a housing, an information handling resource housed within the housing, a first air intake vent formed in the housing, a second air intake vent formed in the housing, a first air mover located proximate to the first air intake vent and configured to draw air into the housing via the first air intake vent, and a second air mover located substantially further away from the first air intake vent than the first air mover, located substantially further away from the second air intake vent than the first air mover is located from the first air intake vent, and configured to draw air into the housing via the second air intake vent.

In accordance with these and other embodiments of the present disclosure, an air mover may include an air mover housing and an impeller housed substantially within the air mover housing and rotationally coupled to the air mover housing about an axis. The air mover housing may include an outlet formed within the air mover housing for expelling air, an inlet formed within the air mover housing for drawing air into the air mover housing, and a series of one or more step-down features formed between the inlet and a surface of the air mover housing in which the depth of successive step-down features from the surface increases from the surface to the inlet.

In accordance with these and other embodiments of the present disclosure, a method may include forming an air mover by rotationally coupling an impeller to an air mover housing about an axis and housing the impeller substantially within the air mover housing, forming an outlet within the air mover housing for expelling air, forming an inlet within the air mover housing for drawing air into the air mover housing, and forming a series of one or more step-down features between the inlet and a surface of the air mover housing in which the depth of successive step-down features from the surface increases from the surface to the inlet.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates selected components of an example notebook, in accordance with embodiments of the present disclosure;

FIG. 3A illustrates an isometric perspective view of a bottom of a keyboard assembly depicting selected components of the notebook depicted in FIG. 2, in accordance with embodiments of the present disclosure;

FIG. 3B illustrates an isometric perspective view of a top and back side of the keyboard assembly depicted in FIG. 3A and depicting selected components of the notebook depicted in FIG. 2, in accordance with embodiments of the present disclosure;

FIG. 3C illustrates an isometric perspective view of the bottom and a front side of the keyboard assembly depicted in FIG. 3B, with a bottom cover of the keyboard assembly removed and depicting selected components of the notebook depicted in FIG. 2, in accordance with embodiments of the present disclosure;

FIG. 4A illustrates an isometric perspective view of selected components of an air mover having a cover with a step-shaped geometry proximate to an opening of an air mover housing of the air mover, in accordance with embodiments of the present disclosure; and

FIG. 4B illustrates a side elevation view of selected components of the air mover depicted in FIG. 4A, in accordance with embodiments of the present disclosure.

### DETAILED DESCRIPTION

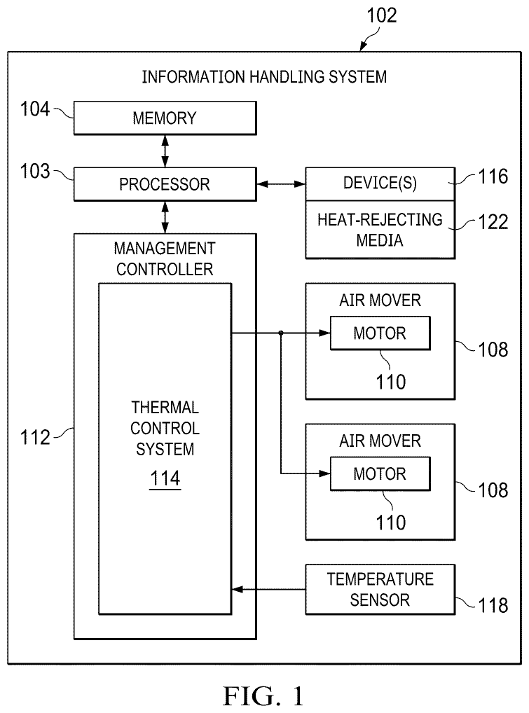

Preferred embodiments and their advantages are best understood by reference to FIGS. 1 through 4B, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, a plurality of air movers 108, a management controller 112, one or more devices 116 communicatively coupled to processor 103, a temperature sensor 118, and heat-rejecting media 122 thermally coupled to device(s) 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

An air mover 108 may include any mechanical or electro-mechanical system, apparatus, or device operable to move air and/or other gases in order to cool information handling resources of information handling system 102. In some embodiments, an air mover 108 may comprise a fan (e.g., a rotating arrangement of vanes or blades which act on the air). In other embodiments, an air mover 108 may comprise a blower (e.g., a centrifugal fan that employs rotating impellers to accelerate air received at its intake and change the direction of the airflow). In these and other embodiments, rotating and other moving components of an air mover 108 may be driven by a motor 110. The rotational speed of motor 110 may be controlled by an air mover control signal (e.g., a pulse-width modulation signal) communicated from thermal control system 114 of management controller 112. In operation, an air mover 108 may cool information handling resources of information handling system 102 by drawing cool air into an enclosure housing the information handling resources from outside the chassis, expelling warm air from inside the enclosure to the outside of such enclosure, and/or moving air across or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air movers 108. Thermal control for air movers 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air movers 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device(s) 116, as shown in FIG. 1), thus reducing a temperature of the information handling resource. For example, heat-rejecting media 122 may include one or more solids thermally coupled to the information handling resource (e.g., heat pipe, heat spreader, heatsink, finstack, etc.) such that heat generated by the information handling resource is transferred from the information handling resource. Further, heat-rejecting media 122 may be arranged to be located within the airflow path of airflow generated by air movers 108, such that heat transferred to heat-rejecting media 122 from device 116 may further be transferred to such airflow. Although, for purposes of clarity and exposition, heat-rejecting media 122 is shown as being thermally coupled to device(s) 116, it is understood that heat-rejecting media 122 may also be thermally coupled to other information handling resources (e.g., processor 103 and/or memory 104) of information handling system 102 in addition to or in lieu of being thermally coupled to device 116.

In addition to processor 103, memory 104, air mover 108, management controller 112, device(s) 116, temperature sensor 118, and heat-rejecting media 122, information handling system 102 may include one or more other information handling resources. In addition, for the sake of clarity and exposition of the present disclosure, FIG. 1 depicts two air movers 108 and one temperature sensor 118. In embodiments of the present disclosure, information handling system 102 may include any number of air movers 108 and temperature sensors 118.

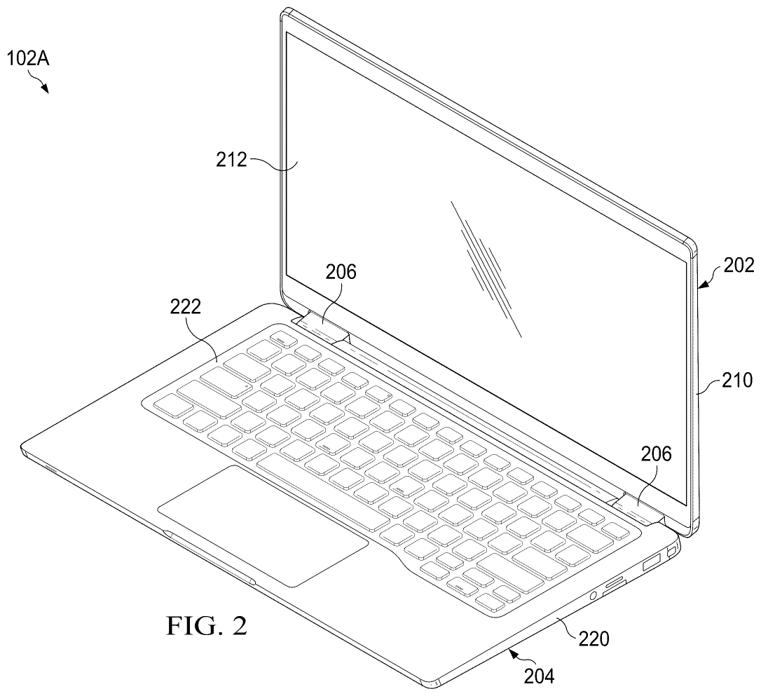

FIG. 2 illustrates selected components of an example notebook 102A, in accordance with embodiments of the present disclosure. Notebook 102A may implement information handling system 102. As shown in FIG. 2, notebook 102A may include a display assembly 202 and a keyboard assembly 204 rotatably coupled to one another via one or more hinges 206. Display assembly 202 may comprise a housing 210 that may house components of notebook 102A including a display device 212 (e.g., liquid crystal display) for outputting alphanumeric and/or graphical output. Keyboard assembly 204 may comprise a housing 220 that may house components of notebook 102A including a keyboard 222 for inputting information to notebook 102A. Keyboard assembly 204 may also include other components of information handling system 102 (e.g., processor 103, memory 104, management controller 112, device(s) 116, air movers 108, temperature sensor 118, heat-rejecting media 122, etc.) not explicitly depicted in FIG. 2.

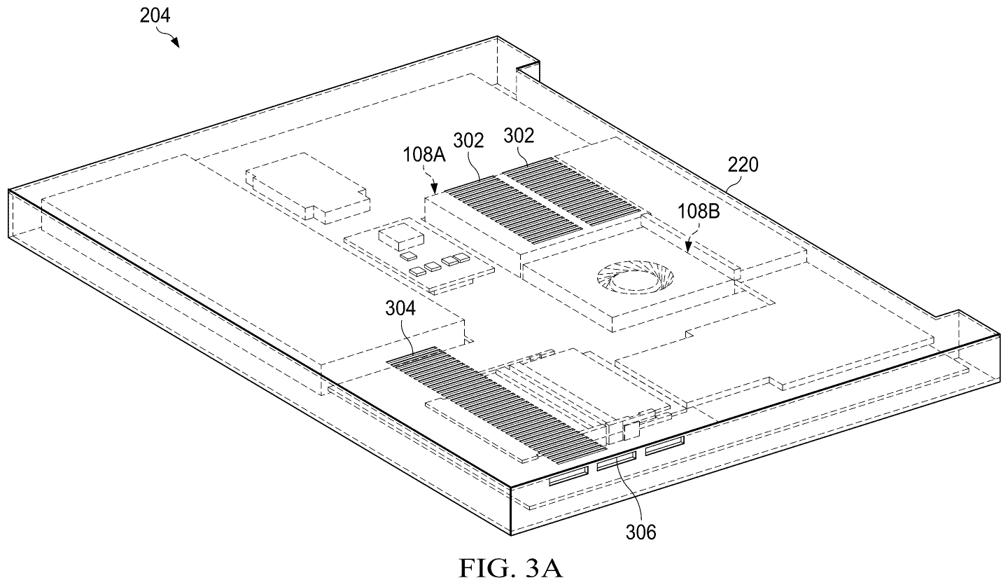

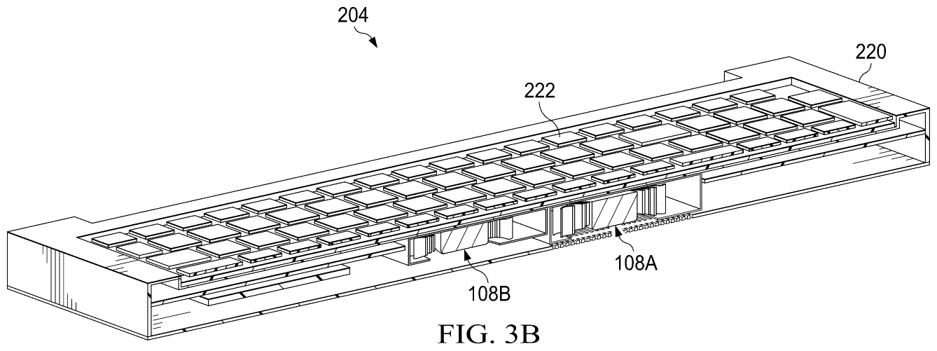

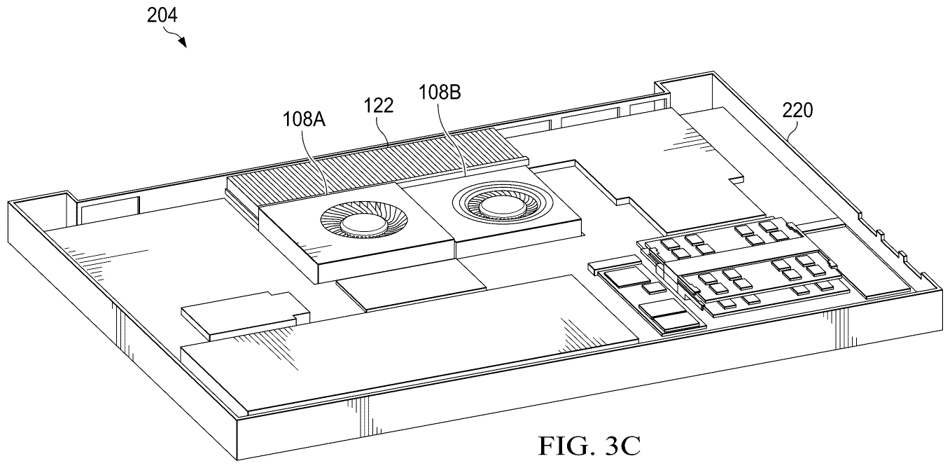

FIG. 3A illustrates an isometric perspective view of a bottom of keyboard assembly 204 showing selected components of notebook 102A, in accordance with embodiments of the present disclosure. In FIG. 3A, for purposes of clarity and exposition, a bottom cover (e.g., a “D-cover”) of housing 220 of keyboard assembly 204 is shown as partially transparent to allow FIG. 3A to depict selected components internal to housing 220. FIG. 3B illustrates an isometric perspective view of a top and back side of keyboard assembly 204, in accordance with embodiments of the present disclosure. As in FIG. 3B, portions of housing 220 of keyboard assembly 204 are shown as partially transparent to allow FIG. 3B to depict selected components internal to housing 220. FIG. 3C illustrates an isometric perspective view of a bottom and front side of keyboard assembly 204, with the bottom of housing 220 removed for purposes of clarity and exposition, in accordance with embodiments of the present disclosure.

As shown in FIGS. 3A-3C, housing 220 of keyboard assembly 204 may have formed therein a number of air vents, including local air vents 302, remote air vent 304 formed on the bottom of housing 220, and remote air vent 306 formed on the side of housing 220. Of air movers 108, one or more air movers 108A may be located within housing 220 proximate to local air vents 302 while one or more air movers 108B may not be proximate to any of vents 302, 304, and 306. In operation, air mover 108A may draw air mainly from local air vents 302 while air mover 108B may draw air mainly from remote air vents 304 and 306.

By drawing air from remote air vents 304 and 306, cool air may travel throughout the interior of housing 220 before entering air mover 108B. Due to cool air being driven over such a path, the arrangement shown in FIGS. 3A-3C may directly minimize skin temperature of housing 220 as compared to traditional approaches in which air movers intake air through vents close in proximity to the air movers. Accordingly, in operation, air mover 108A proximate to local air vents may efficiently regulate temperature of heat-producing components of notebook 102A, such as CPUs and/or GPUs, while air mover 108B located significantly further from remote air vents 304 and 306 may effectively manage skin temperature of housing 220.

However, because the bottom cover of housing 220 does not include a local vent 302 directly under air mover 108B, air mover 108B may require a significant air gap (e.g., 3.5mm) between it and the cover of housing 220 in order to minimize airflow impedance of the air flow path of air mover 108B. Because of this required air gap, air mover 108B may be thinner than air mover 108A, and thus may drive air at a lower airflow rate as compared to air mover 108A when operating at the same speeds.

To overcome this problem, a housing for air mover 108B may include geometric features to maximize a volume of space between the housing of air mover 108B and the bottom of housing 220, as described in greater detail below.

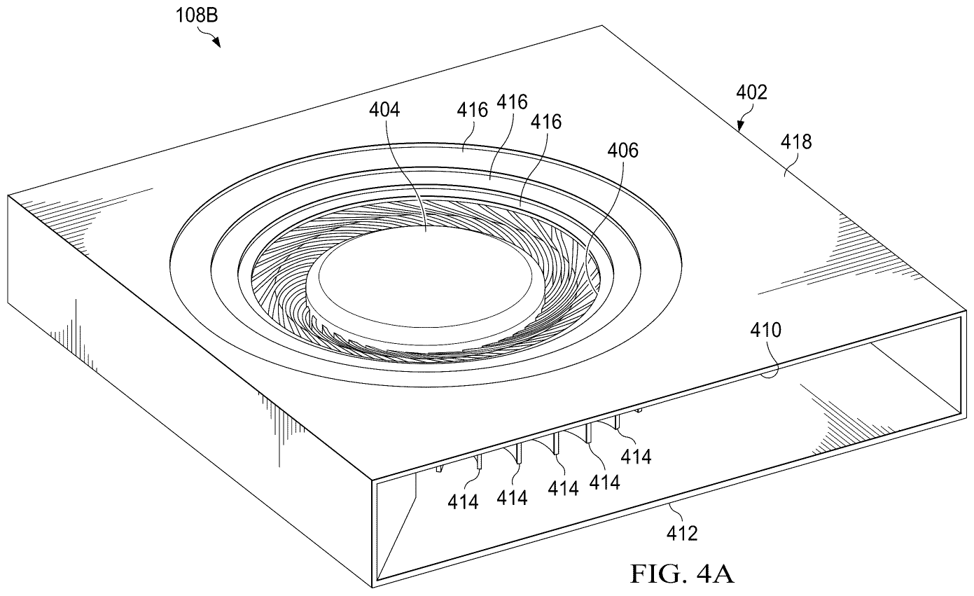

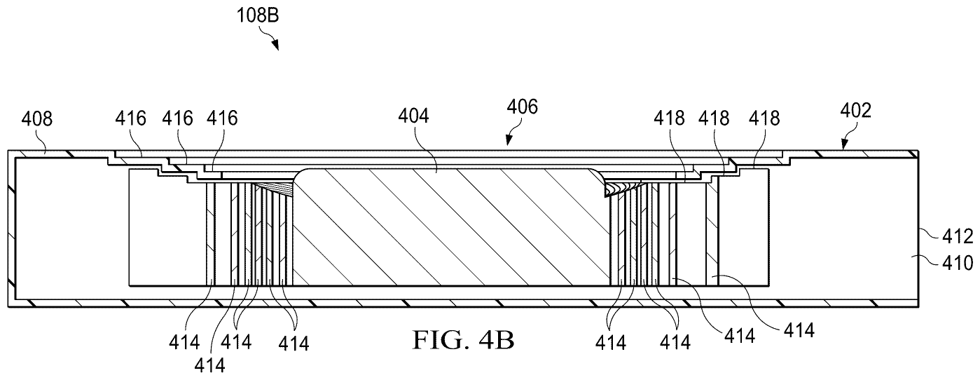

FIG. 4A illustrates an isometric perspective view of selected components of air mover 108B, in accordance with embodiments of the present disclosure. In particular, FIG. 4A depicts a view of a bottom of air mover 108B (i.e., the portion of air mover 108B closest in proximity to the bottom (i.e., D-cover) of housing 220 which is opposite from keyboard 222 within housing 220. FIG. 4B illustrates a side elevation view of selected components air mover 108B, in accordance with embodiments of the present disclosure. In particular, FIG. 4B depicts the bottom of air mover 108B at the top of FIG. 4B and the top of air mover 108B at the bottom of FIG. 4B.

As shown in FIGS. 4A and 4B, air mover 108B may comprise a housing 402 and an impeller 404 located substantially within housing 402. As also shown in FIGS. 4A and 4B, housing 402 may include an inlet 406 which may be formed within a bottom cover 408 of housing 402 and an exhaust 410 formed in a side 412 of housing 402. Impeller 404 may be rotationally coupled to housing 402 about an axis, and may include a plurality of fins 414. In operation, a motor (e.g., motor 110 shown in FIG. 1) may cause impeller 404 to rotate about its axis relative to housing 402, causing air to be drawn into housing 402 via inlet 406 and expelled from housing 402 via exhaust 410.

To maximize a volume of space between housing 402 of air mover 108B and the bottom of housing 220, the bottom of housing 402 may have formed therein a series of one or more step-down features 416 from a surface 418 of bottom cover 408 to inlet 406, in which the depth of successive step-down features 416 increases from surface 418 to inlet 406. For example, as shown in FIGS. 4A and 4B, in embodiments in which inlet 406 is circular in shape, each step-down feature 416 may be concentric about the axis of impeller 404.

In some embodiments, fins 414 may have step-down features 418 corresponding to step-down features 416, in order to maximize area of fins 414 within housing 402. Accordingly, each corresponding step-down feature may be configured (e.g., sized and shaped) to correspond to the respective step-down feature 416.

Although inlet 406 and step-down features 416 are depicted in FIGS. 4A and 4B as circular, it is understood that inlet 406 and step-down features 416 may be of any suitable shape.

While the terms “top,” “bottom,” “front,” “back,” and “side” are used for purposes of exposition and clarity, such terms are not intended to limit any of the components disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. An information handling system comprising:
a housing;
an information handling resource housed within the housing;
a first air intake vent formed in the housing;
a second air intake vent formed in the housing;
a first air mover located proximate to the first air intake vent and configured to draw air into the housing via the first air intake vent; and
a second air mover located substantially further away from the first air intake vent than the first air mover, located substantially further away from the second air intake vent than the first air mover is located from the first air intake vent, and configured to draw air into the housing via the second air intake vent.

2. The information handling system of claim 1, wherein the first air mover is thicker than the second air mover.

3. The information handling system of claim 1, wherein the second air mover comprises:
an air mover housing; and
an impeller housed substantially within the housing and rotationally coupled to the housing about an axis;
wherein the air mover housing comprises:
an outlet formed within the air mover housing for expelling air;
an inlet formed within the air mover housing for drawing air into the air mover housing; and
a series of one or more step-down features formed between the inlet and a surface of the housing, in which the depth of successive step-down features from the surface increases from the surface to the inlet.

4. The information handling system of claim 3, wherein:
the inlet is circular in shape;
each of the one or more step-down features is circular in shape; and
the inlet and the one or more step-down features are concentric about the axis.

5. The information handling system of claim 3, wherein the impeller comprises a plurality of fins for driving airflow, wherein each of the plurality of fins have one or more corresponding step-down features, each of the one or more corresponding step-down features configured to correspond to a respective one of the one or more step-down features.

6. An air mover comprising:
an air mover housing; and
an impeller housed substantially within the air mover housing and rotationally coupled to the air mover housing about an axis;
wherein the air mover housing comprises:
an outlet formed within the air mover housing for expelling air;
an inlet formed within the air mover housing for drawing air into the air mover housing; and
a series of one or more step-down features formed between the inlet and a surface of the air mover housing in which the depth of successive step-down features from the surface increases from the surface to the inlet.

7. The air mover of claim 6, wherein:
the inlet is circular in shape;
each of the one or more step-down features is circular in shape; and
the inlet and the one or more step-down features are concentric about the axis.

8. The air mover of claim 6, wherein the impeller Comprises a plurality of fins for driving airflow, wherein each of the plurality fins have one or more corresponding step-down features, each of the one or more corresponding step-down features configured to correspond to a respective one of the one or more step-down features.

9. A method comprising forming an air mover by:
rotationally coupling an impeller to an air mover housing about an axis and housing the impeller substantially within the air mover housing;
forming an outlet within the air mover housing for expelling air;
forming an inlet within the air mover housing for drawing air into the air mover housing; and
forming a series of one or more step-down features between the inlet and a surface of the air mover housing in which the depth of successive step-down features from the surface increases from the surface to the inlet.

10. The method of claim 9, further comprising:
forming the inlet to be circular in shape;
forming each of the one or more step-down features to be circular in shape; and
forming the inlet and the one or more step-down features to be concentric about the axis.

11. The method of claim 9, further comprising forming, on each fin of the impeller, one or more corresponding step-down features, each of the one or more corresponding step-down features configured to correspond to a respective one of the one or more step-down features.

12. The method of claim 9, comprising:
forming a first air intake vent in an information handling system housing;
forming a second air intake vent in the information handling system housing;
housing a second air mover in the information handling system housing proximate to the first air intake vent such that the second air mover is configured to draw air into the information handling system housing via the first air intake vent; and
housing the air mover within the information handling system housing at a location substantially further away from the first air intake vent than the second air mover and a location substantially further away from the second air intake vent than the second air mover is located from the first air intake vent, such that the air mover is configured to draw air into the information handling system housing via the second air intake vent.
